(19) United States
(12) Patent Application Publication
(10) Pub. No.: US 2022/0205125 A1
(43) Pub. Date: Jun. 30, 2022

(54) PLATING APPARATUS AND OPERATION CONTROL METHOD OF PLATING APPARATUS

(71) Applicant: EBARA CORPORATION, Tokyo (JP)

(72) Inventor: Masaki Tomita, Tokyo (JP)

(21) Appl. No.: 17/441,647

(22) PCT Filed: Dec. 28, 2020
(86) PCT No.: PCT/JP2020/049156

§ 371 Date: Sep. 21, 2021

(51) Int. Cl. C25D 17/06; C25D 21/12

(52) U.S. Cl. CPC C25D 17/06; C25D 21/12

(57) ABSTRACT

A plating apparatus for performing a plating process on a substrate includes a first robot chamber, a plating chamber, a first processing chamber, a second robot chamber, a first door, a second door, and a control module. The first robot chamber houses a first transfer robot for transferring a substrate. The first processing chamber houses a pre-process module. The second robot chamber houses a second transfer robot for transferring a substrate between the pre-process module and the plating module. The first door is arranged between the first robot chamber and the first processing chamber. The second door is arranged between the first processing chamber and the second robot chamber. The control module is configured to control opening and closing of the first door and the second door such that the first door and the second door do not simultaneously open.

### TECHNICAL FIELD

This application relates to a plating apparatus and an operation control method of the plating apparatus.

### BACKGROUND ART

There has been known a cup type electroplating apparatus as one example of a plating apparatus. The cup type electroplating apparatus includes a plating module for performing a plating process on a substrate. The plating module holds a substrate (for example, a semiconductor wafer) with a surface to be plated facing downward and deposits a conductive film on the surface of the substrate by immersing the substrate in a plating solution and applying a voltage between the substrate and an anode.

The cup type electroplating apparatus includes various constituent elements other than the plating module. For example, the plating apparatus includes a first transfer robot for transferring a substrate loaded to the plating apparatus and a substrate to be unloaded from the plating apparatus and an aligner for adjusting a notch direction of a substrate. Further, the plating apparatus includes a pre-process module for performing a pre-process for a plating process, a post-process module for performing a post-process for the plating process, and a second transfer robot for transferring a substrate between the respective modules.

The first transfer robot transfers the substrate loaded to the plating apparatus to the aligner and passes the substrate whose notch direction has been adjusted by the aligner to the second transfer robot. The second transfer robot transfers the substrate received from the first transfer robot to the pre-process module and transfers the substrate on which the pre-process has been completed to the plating module. The second transfer robot transfers the substrate on which the plating process has been completed to the post-process module and passes the substrate on which the post-process has been completed to the first transfer robot. The first transfer robot unloads the substrate received from the second transfer robot from the plating apparatus.

### CITATION LIST

### Patent Literature

PTL 1: Japanese Unexamined Patent Application Publication No. 2018-9215

### SUMMARY OF INVENTION

### Technical Problem

The conventional plating apparatus has a room for improvement in arrangement and an operation control of constituent elements for reducing contamination of particles generated related to the plating process.

That is, in the plating apparatus, there is a possibility that particles caused by the plating process are generated in the plating module and the particles are mixed in spaces where other constituent elements are housed from a space where the plating module is housed. For example, in the related art, by gripping or releasing the substrate between the first transfer robot and the second transfer robot, a chamber where the first transfer robot is housed and a chamber where the second transfer robot is housed become in a communication state in some cases. When this causes the particles to mix in the chamber where the first transfer robot is housed from the chamber where the second transfer robot is housed, the particles are possibly accumulated on the substrate to be unloaded from the plating apparatus. There is a possibility that this kind of contamination of the particles causes degradation of quality of the substrate on which the plating process is performed, and as a result, causes a production yield to degrade.

Therefore, one object of this application is to optimize arrangement and an operation control of constituent elements of a plating apparatus for reducing contamination of particles.

### Solution to Problem

According to one embodiment, a plating apparatus for performing a plating process on a substrate is disclosed. The plating apparatus includes a first robot chamber, a plating chamber, a first processing chamber, a second robot chamber, a first door, a second door, and a control device. The first robot chamber houses a first transfer robot for transferring a substrate loaded to the plating apparatus and a substrate to be unloaded from the plating apparatus. The plating chamber houses a plating module for performing a plating process on a substrate. The first processing chamber houses a pre-process module for performing a pre-process for a plating process on a substrate. The second robot chamber houses a second transfer robot for transferring a substrate between the pre-process module and the plating module. The first door is arranged between the first robot chamber and the first processing chamber. The second door is arranged between the first processing chamber and the second robot chamber. The control device is configured to control opening and closing of the first door and the second door such that the first door and the second door do not simultaneously open.

### BRIEF DESCRIPTION OF DRAWINGS

FIG. 1 is a perspective view illustrating an overall configuration of a plating apparatus of this embodiment.

FIG. 2 is a plan view illustrating the overall configuration of the plating apparatus of this embodiment.

FIG. 3 is a view schematically illustrating a configuration of a hand of a second transfer robot.

FIG. 4 is a flowchart of an operation control of the plating apparatus of this embodiment.

### DESCRIPTION OF EMBODIMENTS

The following describes an embodiment of the present invention with reference to the drawings. In the drawings described later, the identical reference numerals are assigned for the identical or equivalent constituent elements, and therefore such elements will not be further elaborated here.

<Overall Configuration of Plating Apparatus>

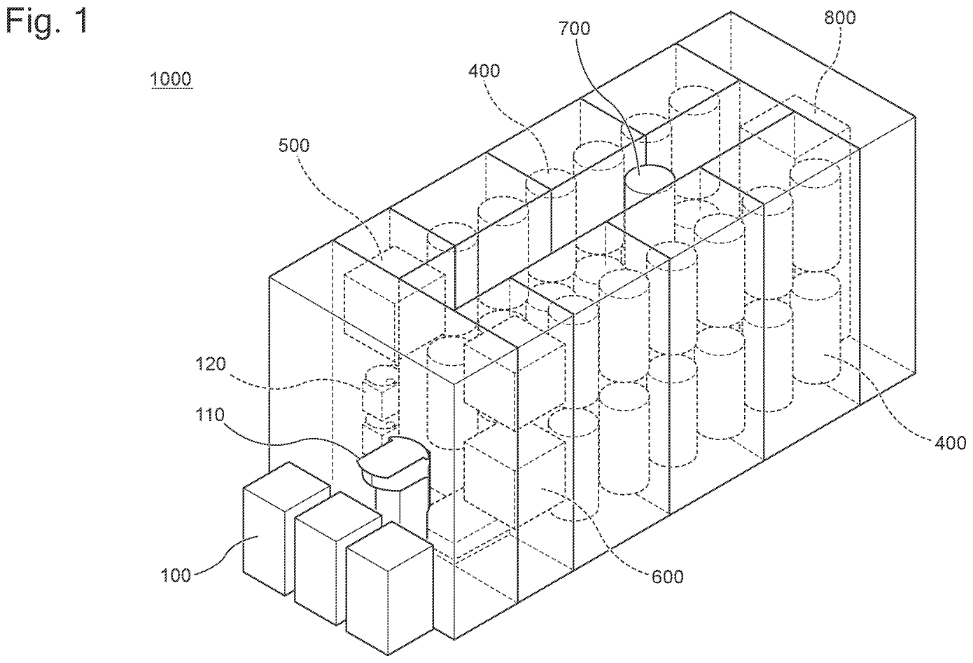

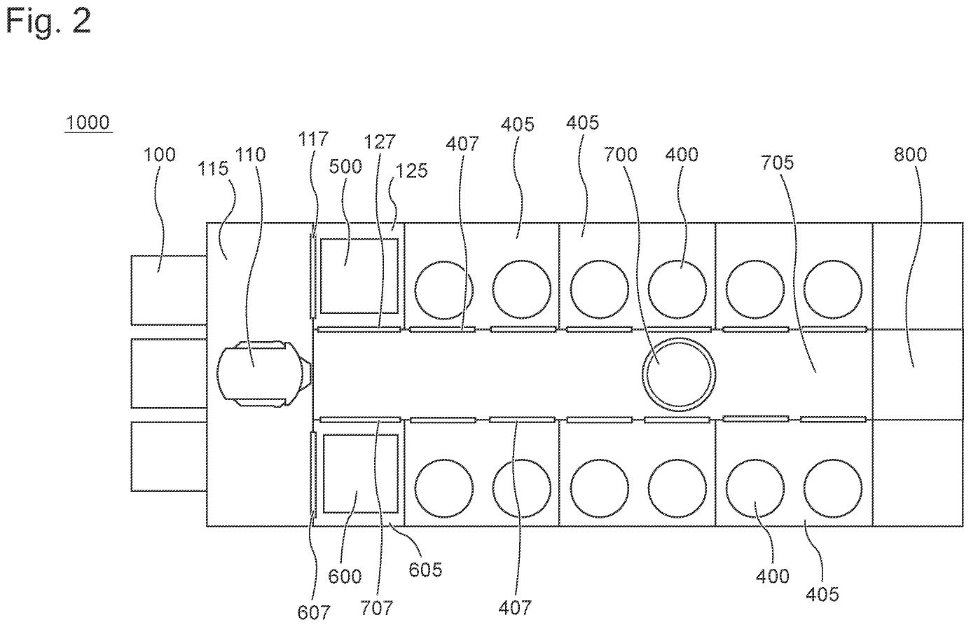

FIG. 1 is a perspective view illustrating an overall configuration of a plating apparatus of this embodiment. FIG. 2 is a plan view illustrating the overall configuration of the plating apparatus of this embodiment. As illustrated in FIG. 1 and FIG. 2, a plating apparatus 1000 includes load ports 100, a first transfer robot 110, aligners 120, plating modules 400, a cleaning module 500, spin rinse dryers 600, a second transfer robot 700, and a control module 800.

The load port 100 is a module for loading a substrate housed in a cassette, such as a FOUP, (not illustrated) to the plating apparatus 1000 and unloading the substrate from the plating apparatus 1000 to the cassette. The load port 100 is arranged adjacent to a first robot chamber 115 that houses the first transfer robot 110. While the three load ports 100 are arranged in a horizontal direction in this embodiment, the number of load ports 100 and arrangement of the load ports 100 are arbitrary.

The first transfer robot 110 is a robot for transferring the substrate that is configured to grip or release the substrate between the load port 100, the aligner 120, and the spin rinse dryer 600. The first transfer robot 110 is housed in the first robot chamber 115.

The aligner 120 is a module for adjusting a position of an orientation flat, a notch, and the like of the substrate in a predetermined direction. The aligner 120 is a kind of pre-process module for performing a pre-process for a plating process on the substrate. The aligner 120 is housed in a first processing chamber 125 adjacent to the first robot chamber 115. While the two aligners 120 are disposed to be arranged in a vertical direction in this embodiment, the number of aligners 120 and arrangement of the aligners 120 are arbitrary. While the aligner 120 has been described as an example of the pre-process module in this embodiment, but it is not limited thereto. The pre-process module may include a pre-wet module for supplying pure water or deaerated water to the substrate. The pre-wet module wets a surface to be plated of the substrate before the plating process with a process liquid, such as the pure water or the deaerated water, to replace air inside a pattern formed on the surface of the substrate with the process liquid. Further, the pre-process module may include a pre-soak module for supplying an etching process liquid to the substrate. The pre-soak module is configured to remove an oxidized film having a large electrical resistance present on a surface of a seed layer or the like formed on the surface to be plated of the substrate before the plating process by etching with a process liquid, such as sulfuric acid and hydrochloric acid, and perform a pre-soak process that cleans or activates a surface of a plating base layer.

The plating module 400 is a module for performing the plating process on the substrate. There are two sets of the 12 plating modules 400 arranged by two in the vertical direction and by six in the horizontal direction, and the total 24 plating modules 400 are disposed in this embodiment, but the number of plating modules 400 and arrangement of the plating modules 400 are arbitrary. The plating modules 400 are housed in plating chambers 405.

The cleaning module 500 is configured to perform a cleaning process on the substrate to remove the plating solution or the like left on the substrate after the plating process. While the one cleaning module 500 is arranged in the first processing chamber 125 in this embodiment, the number of cleaning modules 500 and arrangement of the cleaning modules 500 are arbitrary. The cleaning module 500 is a kind of first post-process module for performing a post-process for the plating process on the substrate.

The spin rinse dryer 600 is a module for rotating the substrate after the cleaning process at high speed and drying the substrate. While two spin rinse dryers are disposed to be arranged in the vertical direction in this embodiment, the number of spin rinse dryers and arrangement of the spin rinse dryers are arbitrary. The spin rinse dryer 600 is a kind of second post-process module for performing a post-process for the plating process on the substrate. The spin rinse dryer 600 is housed in a second processing chamber 605. While an example in which the cleaning module 500 is used as the first post-process module and the spin rinse dryer 600 is used as the second post-process module is indicated in this embodiment, but it is not limited thereto. Without limiting to the above example, as the first post-process module or the second post-process module, an edge back rinse module for supplying the process liquid to an outer peripheral portion of the substrate can be used.

The second transfer robot 700 is a device for transferring the substrate between a plurality of modules inside the plating apparatus 1000. Specifically, the second transfer robot 700 transfers the substrate between the pre-process module including the aligner 120, the plating module 400, the first post-process module including the cleaning module 500, and the second post-process module including the spin rinse dryer 600. The second transfer robot 700 is housed in a second robot chamber 705 adjacent to the first processing chamber 125, the plating chambers 405, and the second processing chamber 605.

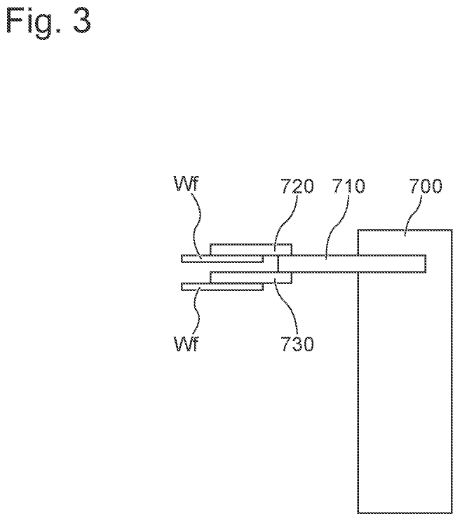

FIG. 3 is a view schematically illustrating a configuration of a hand of a second transfer robot. As illustrated in FIG. 3, the second transfer robot 700 includes a first hand 720, a second hand 730, and an arm 710 for holding the first hand 720 and the second hand 730. The first hand 720 is a dry-only hand for transferring a substrate Wf before the plating process is performed. The second hand 730 is a wet-only hand for transferring the substrate Wf after the plating process is performed and arranged underneath the first hand 720. This can prevent a liquid, such as the plating solution, from dripping from the substrate Wf held by the second hand 730 to the first hand 720.

The first robot chamber 115 is a region that needs to be kept in the cleanest state. In view of this, a pressure inside the first robot chamber 115 is always maintained higher than that of any of outsides of the plating modules 400, the first processing chamber 125, the second processing chamber 605, the second robot chamber 705, and the plating chambers 405. On the other hand, since particles at a molecular level are generated by vaporization of a chemical liquid in a wet process, such as the plating process, the plating chambers 405 become the dirtiest region. Accordingly, a negative pressure is formed inside the plating chambers 405. An inside of the plating module 400 is adjusted such that the pressure becomes lower in an order of the first robot chamber 115, the first processing chamber 125 and the second processing chamber 605, the second robot chamber 705, and the plating chambers 405.

The control module 800 is configured to control the plurality of modules in the plating apparatus 1000 and can be configured of, for example, a general computer including input/output interfaces with an operator or a dedicated computer. The control module 800 is housed in a control chamber 805.

In the plating apparatus 1000 of this embodiment, the first robot chamber 115, the first processing chamber 125, the second processing chamber 605, the second robot chamber 705, and the plating chambers 405 are mutually separated. This ensures a mini-environment, in the plating apparatus 1000, in which each of the first transfer robot 110, the aligners 120 and the cleaning module 500, the spin rinse dryers 600, the second transfer robot 700, and the plating modules 400 are arranged in the separated chambers. The plating apparatus 1000 is configured to open the separation between the respective chambers in a limited way only when the substrate is gripped or released. This point will be described below.

The control module 800 is configured to control opening and closing of doors that divide a plurality of chambers housing various constituent elements of the plating apparatus 1000. Specifically, as illustrated in FIG. 2, the plating apparatus 1000 includes a first door 117 arranged between the first robot chamber 115 and the first processing chamber 125. The control module 800 is configured to control the opening and closing of the first door 117. For example, the control module 800 opens the first door 117 when the substrate is gripped or released from the first transfer robot 110 to the aligner 120.

The plating apparatus 1000 includes a second door 127 arranged between the first processing chamber 125 and the second robot chamber 705. The control module 800 is configured to control the opening and closing of the second door 127. For example, the control module 800 opens the second door 127 when the second transfer robot 700 receives the substrate whose notch direction has been adjusted by the aligner 120.

Further, the plating apparatus 1000 includes a third door 707 arranged between the second robot chamber 705 and the second processing chamber 605. The control module 800 is configured to control the opening and closing of the third door 707. For example, the control module 800 opens the third door 707 when the substrate on which the plating process has been performed is gripped or released from the second transfer robot 700 to the spin rinse dryer 600.

Further, the plating apparatus 1000 includes a fourth door 607 arranged between the second processing chamber 605 and the first robot chamber 115. The control module 800 is configured to control the opening and closing of the fourth door 607. For example, the control module 800 opens the fourth door 607 when the first transfer robot 110 receives the substrate on which a drying process has been performed by the spin rinse dryer 600.

Further, the plating apparatus 1000 includes a plurality of fifth doors 407 arranged between the second robot chamber 705 and the plating chambers 405. The control module 800 is configured to control the opening and closing of the fifth doors 407. For example, the control module 800 opens the fifth door 407 when the second transfer robot 700 grips or releases the substrate to the plating module 400.

The control module 800 is configured to control the opening and closing of the first door 117 and the second door 127 such that the first door 117 and the second door 127 do not simultaneously open. Further, the control module 800 is configured to control the opening and closing of the third door 707 and the fourth door 607 such that the third door 707 and the fourth door 607 do not simultaneously open.

That is, the plating apparatus 1000 of this embodiment is configured to reduce contamination of the particles into the first robot chamber 115 that needs to be kept in the cleanest state. Specifically, the plating apparatus 1000 is configured to grip or release the substrate via the aligner 120 or the spin rinse dryer 600 without gripping or releasing the substrate between the first transfer robot 110 and the second transfer robot 700. Here, when the substrate is gripped or released from the first transfer robot 110 to the aligner 120, the first door 117 is opened. However, the second door 127 is closed at this time. Further, when the second transfer robot 700 receives the substrate whose notch direction has been adjusted by the aligner 120, the second door 127 is opened. However, the first door 117 is closed at this time. Furthermore, when the substrate on which the plating process has been performed is gripped or released from the second transfer robot 700 to the spin rinse dryer 600, the third door 707 is opened. However, the fourth door 607 is closed at this time. Furthermore, when the first transfer robot 110 receives the substrate on which the drying process has been performed by the spin rinse dryer 600, the fourth door 607 is opened. However, the third door 707 is closed at this time.

Since this causes the first robot chamber 115 and the second robot chamber 705 to be not in a communication state, mixing the particles accumulated on the second transfer robot 700 in the first robot chamber 115 can be reduced. Thus, since arrangement and an operation control of the constituent elements are optimized in the plating module 400 of this embodiment, mixing the particles in the first robot chamber 115 can be reduced, and as a result, accumulating the particles on the substrate to be unloaded from the plating module 400 can be reduced.

Note that, similarly to the second door 127 and the fifth doors 407, the control module 800 is configured to control the opening and closing of the second door 127 and the fifth doors 407 such that both do not simultaneously open. Furthermore, similarly to the third door 707 and the fifth doors 407, the control module 800 is configured to control the opening and closing of the third door 707 and the fifth doors 407 such that both do not simultaneously open.

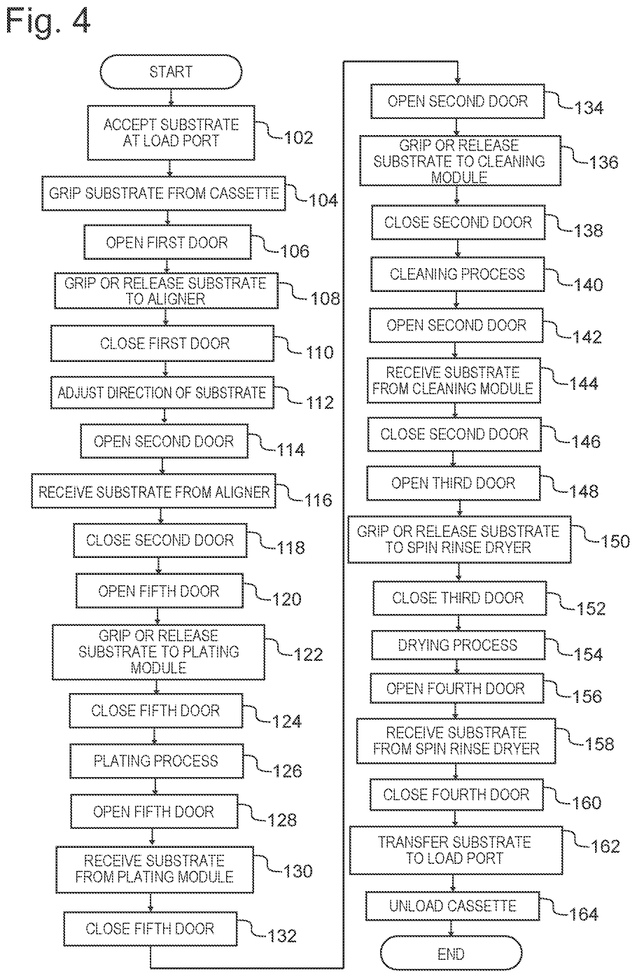

Next, an example of a sequence of the operation control of the plating apparatus 1000 will be described. FIG. 4 is a flowchart of the operation control of the plating apparatus 1000 of this embodiment. First, the plating apparatus 1000 accepts the substrate housed in the cassette at the load port 100 (step 102). Subsequently, the plating apparatus 1000 grips the substrate from the cassette at the load port 100 by the first transfer robot 110 (step 104). Subsequently, the control module 800 opens the first door 117 (step 106). Subsequently, the plating apparatus 1000 grips or releases the substrate to the aligner 120 by the first transfer robot 110 (first gripping or releasing step 108). Subsequently, the control module 800 closes the first door 117 (step 110).

Subsequently, the plating apparatus 1000 adjusts the position of the orientation flat, the notch, or the like of the substrate in the predetermined direction by the aligner 120 (step 112). Subsequently, the control module 800 opens the second door 127 (step 114). Subsequently, the plating apparatus 1000 receives the substrate whose direction has been adjusted from the aligner 120 by the first hand 720 of the second transfer robot 700 (first receiving step 116). Subsequently, the control module 800 closes the second door 127 (step 118).

Subsequently, the control module 800 opens the fifth door 407 (step 120). Subsequently, the plating apparatus 1000 grips or releases the substrate to the plating module 400 by the first hand 720 of the second transfer robot 700 (step 122). Subsequently, the control module 800 closes the fifth door 407 (step 124). Subsequently, the plating apparatus 1000 performs the plating process on the substrate by the plating module 400 (step 126). Subsequently, the control module 800 opens the fifth door 407 (step 128). Subsequently, the plating apparatus 1000 receives the substrate from the plating module 400 by the second hand 730 of the second transfer robot 700 (step 130). Subsequently, the control module 800 closes the fifth door 407 (step 132).

Subsequently, the control module 800 opens the second door 127 (step 134). Subsequently, the plating apparatus 1000 grips or releases the substrate to the cleaning module 500 by the second hand 730 of the second transfer robot 700 (step 136). Subsequently, the control module 800 closes the second door 127 (step 138). Subsequently, the plating apparatus 1000 performs the cleaning process on the substrate by the cleaning module 500 (step 140).

Subsequently, the control module 800 opens the second door 127 (step 142). Subsequently, the plating apparatus 1000 receives the substrate from the cleaning module 500 by the second hand 730 of the second transfer robot 700 (step 144). Subsequently, the control module 800 closes the second door 127 (step 146).

Subsequently, the control module 800 opens the third door 707 (step 148). Subsequently, the plating apparatus 1000 grips or releases the substrate to the spin rinse dryer 600 by the second hand 730 of the second transfer robot 700 (second gripping or releasing step 150). Subsequently, the control module 800 closes the third door 707 (step 152).

Subsequently, the plating apparatus 1000 performs the drying process on the substrate by the spin rinse dryer 600 (step 154). Subsequently, the control module 800 opens the fourth door 607 (step 156). Subsequently, the plating apparatus 1000 receives the substrate on which the drying process has been performed by the first transfer robot 110 (second receiving step 158). Subsequently, the control module 800 closes the fourth door 607 (step 160). Subsequently, the plating apparatus 1000 transfers the substrate to the cassette at the load port 100 by the first transfer robot 110 (step 162). Finally, the plating apparatus 1000 unloads the cassette housing the substrate from the load port 100 (step 164).

As described above, with this embodiment, in the plating apparatus that ensures the mini-environment in which a plurality of constituent elements are each arranged in the separated chambers, the opening and closing of the doors between the separated chambers is controlled such that the first robot chamber 115 and the second robot chamber 705 are not in the communication state. This can reduce mixing the particles accumulated on the second transfer robot 700 in the first robot chamber 115.

Although several embodiments of the present invention have been explained above, these embodiments of the invention described above are for the purpose of facilitating the understanding of the present invention, and are not intended to limit the present invention. The present invention may be modified or improved without departing from the gist of the invention, and the present invention obviously includes equivalents thereof. Further, the constituent elements described in the scope of the claims and the specification may be arbitrarily combined or eliminated within a scope in which the above-described problems can be at least partially solved or a scope in which the effects can be at least partially achieved.

As one embodiment, this application discloses a plating apparatus for performing a plating process on a substrate. The plating apparatus includes a first robot chamber, a plating chamber, a first processing chamber, a second robot chamber, a first door, a second door, and a control device. The first robot chamber houses a first transfer robot for transferring a substrate loaded to the plating apparatus and a substrate to be unloaded from the plating apparatus. The plating chamber houses a plating module for performing a plating process on a substrate. The first processing chamber houses a pre-process module for performing a pre-process for a plating process on a substrate. The second robot chamber houses a second transfer robot for transferring a substrate between the pre-process module and the plating module. The first door is arranged between the first robot chamber and the first processing chamber. The second door is arranged between the first processing chamber and the second robot chamber. The control device is configured to control opening and closing of the first door and the second door such that the first door and the second door do not simultaneously open.

Furthermore, as one embodiment, this application discloses a plating apparatus that further includes a second processing chamber, a third door, and a fourth door. The second processing chamber houses a post-process module for performing a post-process for a plating process on a substrate. The third door is arranged between the second robot chamber and the second processing chamber. The fourth door is arranged between the second processing chamber and the first robot chamber. The control device is configured to control opening and closing of the third door and the fourth door such that the third door and the fourth door do not simultaneously open.

Furthermore, as one embodiment, this application discloses a plating apparatus in which the second transfer robot includes a first hand for transferring a substrate before a plating process is performed and a second hand for transferring a substrate after the plating process is performed, the second hand being arranged underneath the first hand.

Furthermore, as one embodiment, this application discloses a plating apparatus in which the pre-process module includes at least one of: an aligner for adjusting a position in a rotation direction of a substrate, a pre-wet module for supplying pure water or deaerated water to a substrate, or a pre-soak module for supplying an etching process liquid to a substrate.

Furthermore, as one embodiment, this application discloses a plating apparatus in which the post-process module includes at least one of: a cleaning module for supplying a cleaning liquid to a substrate, a spin rinse dryer for rotating and drying a substrate, or an edge back rinse module for supplying a process liquid to an outer peripheral portion of a substrate.

Furthermore, as one embodiment, this application discloses an operation control method of a plating apparatus. The operation control method includes: a step of opening a first door arranged between a first robot chamber and a first processing chamber, the first robot chamber housing a first transfer robot for transferring a substrate loaded to a plating apparatus and a substrate to be unloaded from the plating apparatus, the first processing chamber housing a pre-process module for performing a pre-process for a plating process on a substrate; a first gripping or releasing step of gripping or releasing a substrate to the pre-process module by the first transfer robot after the step of opening the first door; a step of closing the first door after the first gripping or releasing step; a step of opening a second door arranged between the first processing chamber and a second robot chamber after the step of closing the first door, the second robot chamber housing a second transfer robot for transferring a substrate between a plating module for performing a plating process on a substrate and the pre-process module; and a first receiving step of receiving a substrate from the pre-process module by the second transfer robot after the step of opening the second door.

Furthermore, as one embodiment, this application discloses an operation control method of a plating apparatus. The operation control method further includes: a step of opening a third door arranged between the second robot chamber and a second processing chamber housing a post-process module for performing a post-process for a plating process on a substrate; a second gripping or releasing step of gripping or releasing a substrate to the post-process module by the second transfer robot after the step of opening the third door; a step of closing the third door after the second gripping or releasing step; a step of opening a fourth door arranged between the second processing chamber and the first robot chamber after the step of closing the third door; and a second receiving step of receiving a substrate from the post-process module by the first transfer robot after the step of opening the fourth door.

Furthermore, as one embodiment, this application discloses an operation control method of a plating apparatus in which the first receiving step is performed using a first hand of the second transfer robot for transferring a substrate before a plating process is performed, and the second gripping or releasing step is performed using a second hand of the second transfer robot for transferring a substrate after a plating process is performed.

### REFERENCE SIGNS LIST

110 . . . first transfer robot
115 . . . first robot chamber
117 . . . first door
120 . . . aligner
125 . . . first processing chamber
127 . . . second door
400 . . . plating module
405 . . . plating chamber
407 . . . fifth door
500 . . . cleaning module
600 . . . spin rinse dryer
605 . . . second processing chamber
607 . . . fourth door
700 . . . second transfer robot
705 . . . second robot chamber
707 . . . third door
720 . . . first hand
730 . . . second hand
800 . . . control module
805 . . . control chamber
1000 . . . plating apparatus

1. A plating apparatus for performing a plating process on a substrate, the plating apparatus comprising:
a first robot chamber housing a first transfer robot for transferring a substrate loaded to the plating apparatus and a substrate to be unloaded from the plating apparatus;
a plating chamber housing a plating module for performing a plating process on a substrate;
a first processing chamber housing a pre-process module for performing a pre-process for a plating process on a substrate;
a second robot chamber housing a second transfer robot for transferring a substrate between the pre-process module and the plating module;
a first door arranged between the first robot chamber and the first processing chamber;
a second door arranged between the first processing chamber and the second robot chamber; and
a control device configured to control opening and closing of the first door and the second door such that the first door and the second door do not simultaneously open.

2. The plating apparatus according to claim 1, further comprising:
a second processing chamber housing a post-process module for performing a post-process for a plating process on a substrate;
a third door arranged between the second robot chamber and the second processing chamber; and
a fourth door arranged between the second processing chamber and the first robot chamber, wherein
the control device is configured to control opening and closing of the third door and the fourth door such that the third door and the fourth door do not simultaneously open.

3. The plating apparatus according to claim 1, wherein
the second transfer robot includes a first hand for transferring a substrate before a plating process is performed and a second hand for transferring a substrate after the plating process is performed, the second hand being arranged underneath the first hand.

4. The plating apparatus according to claim 1, wherein
the pre-process module includes at least one of: an aligner for adjusting a position in a rotation direction of a substrate, a pre-wet module for supplying pure water or deaerated water to a substrate, or a pre-soak module for supplying an etching process liquid to a substrate.

5. The plating apparatus according to claim 1, wherein
the post-process module includes at least one of: a cleaning module for supplying a cleaning liquid to a substrate, a spin rinse dryer for rotating and drying a substrate, or an edge back rinse module for supplying a process liquid to an outer peripheral portion of a substrate.

6. An operation control method of a plating apparatus, comprising:
a step of opening a first door arranged between a first robot chamber and a first processing chamber, the first robot chamber housing a first transfer robot for transferring a substrate loaded to a plating apparatus and a substrate to be unloaded from the plating apparatus, the first processing chamber housing a pre-process module for performing a pre-process for a plating process on a substrate;
a first gripping or releasing step of gripping or releasing a substrate to the pre-process module by the first transfer robot after the step of opening the first door;
a step of closing the first door after the first gripping or releasing step;
a step of opening a second door arranged between the first processing chamber and a second robot chamber after the step of closing the first door, the second robot chamber housing a second transfer robot for transferring a substrate between a plating module for performing a plating process on a substrate and the pre-process module; and
a first receiving step of receiving a substrate from the pre-process module by the second transfer robot after the step of opening the second door.

7. The operation control method of a plating apparatus according to claim 6, further comprising:
a step of opening a third door arranged between the second robot chamber and a second processing chamber housing a post-process module for performing a post-process for a plating process on a substrate;
a second gripping or releasing step of gripping or releasing a substrate to the post-process module by the second transfer robot after the step of opening the third door;
a step of closing the third door after the second gripping or releasing step;
a step of opening a fourth door arranged between the second processing chamber and the first robot chamber after the step of closing the third door; and
a second receiving step of receiving a substrate from the post-process module by the first transfer robot after the step of opening the fourth door.

8. The operation control method of a plating apparatus according to claim 7, wherein
the first receiving step is performed using a first hand of the second transfer robot for transferring a substrate before a plating process is performed, and
the second gripping or releasing step is performed using a second hand of the second transfer robot for transferring a substrate after a plating process is performed.
